(19) United States
(12) Patent Application Publication
(10) Pub. No.: US 2024/0151757 A1
(43) Pub. Date: May 9, 2024

(54) METHOD FOR ACHIEVING TERMINAL-PAIR DEFINITION OF FOUR-TERMINAL-PAIR IMPEDANCE AND APPLICATION THEREOF

(71) Applicant: National Institute of Metrology, China, Beijing (CN)

(72) Inventors: Yan YANG, Beijing (CN); Lu Huang, Beijing (CN); Dongxue Dai, Beijing (CN); Wei WANG, Beijing (CN); Xia LIU, Beijing (CN)

(21) Appl. No.: 18/502,153

(22) Filed: Nov. 6, 2023

(30) Foreign Application Priority Data
Nov. 7, 2022 (CN) 2022113836463

(51) Int. Cl. G01R 27/08; G01R 15/04

(52) U.S. Cl. CPC G01R 27/08; G01R 15/04

(57) ABSTRACT

A method for achieving terminal-pair definition of four-terminal-pair (4TP) impedance and an application thereof are provided, which belongs to the field of precision measurement and metrology. A current output terminal of a two-stage follower is connected to a high current terminal of impedance through a coaxial line, and a voltage output terminal of the two-stage follower is connected to a high voltage terminal of the impedance through the coaxial line, which makes current of the high voltage terminal be 0, and core wire currents and outer wire currents of the high current terminal equal and reverse. The terminal-pair definition of the 4TP impedance can be satisfied; and the follower is added to make a bridge ratio variable and isolate effects of bridge load changes, thereby accelerating a balancing speed of the 4TP impedance bridge, and achieving accurate and fast comparative measurement having high precision of the 4TP AC impedance.

### TECHNICAL FIELD

The present disclosure belongs to the field of precision measurement and metrology, relates to a method for achieving comparative measurement of four-terminal-pair (4TP) impedance by using an alternating current (AC) bridge in electromagnetic metrology, and more particularly to a method for achieving terminal-pair definition of 4TP impedance and an application thereof used to improve a balance speed of this bridge.

### BACKGROUND

AC impedance are fundamental electrical quantities, which includes capacitance, resistance and inductance, and their units farad (F), ohm (Ω), and henry (H) are important derived units in the international system of units (SI). Accurate traceability of the AC impedance involves demands of various fields such as energy, materials, aerospace and military industry.

An accurate comparative measurement for dissemination of the value of quantity (i.e., quantity value) of impedance needs an accurate definition of the AC impedance and an accurate AC bridge technology. A traditional definition of impedance based on terminals and a classic AC bridge technology are no longer able to satisfy accuracy requirements for dissemination of the value of quantity of the impedance. Therefore, researchers propose an AC impedance definition of two-terminal-pair impedance and a measurement technology of a two-terminal-pair AC bridge, an AC impedance definition method based on terminal-pair (i.e., a coaxial port) is introduced by introducing shielding on a basis of a two-terminal-pair (i.e., two-wire) impedance definition.

A disadvantage of the two-terminal-pair impedance definition is that a measuring lead wire still participate in the definition of the impedance. In order to eliminate an effect of the measuring lead wire, the researchers further propose a definition of 4TP AC impedance, and develop a measurement technology for a 4TP AC bridge with high-precision, which makes it possible for dissemination of the value of quantity of the AC impedance with the order of 10⁻⁸ to 10⁻⁹, a series of high-accuracy AC impedance bridges based on induction ratios are formed, which promotes a rapid development of the whole precision electromagnetic measurement technology.

The definition of the 4TP improves the definition of the AC impedance. However, in order to achieve a definition structure of the astatic 4TP AC impedance, a complexity of the AC bridge will be greatly increased, and balance conditions will increase. When using this kind of 4TP bridge to measure, it needs to be adjusted repeatedly, which is time-consuming and cumbersome. Moreover, a bridge operation has a high requirement on measurement operators, which is easy to cause bridge balance error, affect a measurement accuracy of the AC impedance, and is not conducive to a promotion of such measuring instruments.

### SUMMARY

A purpose of the present disclosure is to solve problems existing in the relate art, and provide a method for achieving terminal-pair definition of 4TP impedance and an application thereof, to thereby automatically achieve the 4TP definition of compared impedance of a 4TP impedance bridge, and accurate comparative measurement of AC impedance can be achieved through simply completing a main balance of a bridge, which greatly increases a convergence speed of the 4TP impedance bridge, and achieves a fast comparative measurement of the 4TP impedance.

The present disclosure is achieved through the following technical solutions.

According to a first aspect of the present disclosure, a method for achieving terminal-pair definition of 4TP impedance is provided, and the method includes: connecting a current output terminal of a two-stage follower to a high current terminal of impedance through a coaxial line, and connecting a voltage output terminal of the two-stage follower to a high voltage terminal of the impedance through the coaxial line, to thereby make a current of the high voltage terminal of the impedance be zero, and a core wire current and an outer wire current of the high current terminal equal and reverse.

In an embodiment, the two-stage follower includes: a first follower F₁, a second follower F₂ and a third follower F₃; and the first follower F₁ is a first-stage follower, the second follower F₂ and the third follower F₃ are combined to be a second-stage follower;
a power supply ±V_{cc} of the first-stage follower and a power supply ±V_{cc2} of the second-stage follower are independent of each other, and an output terminal of the first follower F₁ is connected to a center point of the power supply ±V_{cc2} of the second-stage follower; and
an output terminal of the second follower F₂ is connected to a non-inverting input terminal of the third follower F₃.

In an embodiment, the method further includes: connecting an input terminal V_{Input} of the two-stage follower to a non-inverting input terminal of the first follower F₁ and a non-inverting input terminal of the second follower F₂, individually, and connecting the input terminal V_{Input} of the two-stage follower to an outer wire of the input terminal V_{Input} through an input resistance Rᵢₙ;
connecting an output terminal of the third follower F₃ to the current output terminal Iₒᵤₜ of the two-stage follower, and connecting an inverting input terminal of the second follower F₂ to the voltage output terminal Vₒᵤₜ of the two-stage follower;
connecting an outer wire of the current output terminal Iₒᵤₜ of the two-stage follower to a center point of the power supply ±V_{cc} of the first-stage follower; and
connecting an outer wire of the voltage output terminal Vₒᵤₜ of the two-stage follower to the outer wire of the input terminal V_{Input} of the two-stage follower.

In an embodiment, the method further includes: connecting a core wire of the current output terminal Iₒᵤₜ of the two-stage follower to a core wire of the voltage output terminal Vₒᵤₜ of the two-stage follower through a first resistance R₁, and connecting the outer wire of the current output terminal Iₒᵤₜ of the two-stage follower to the outer wire of the voltage output terminal Vₒᵤₜ of the two-stage follower through a second resistance R₂.

According to a second aspect of the present disclosure, a method for achieving fast comparative measurement of a 4TP impedance bridge is provided, and the method uses the above method for achieving terminal-pair definition of 4TP impedance to achieve the fast comparative measurement of the four terminal-pair impedance bridge.

In an embodiment, the method for achieving fast comparative measurement of the 4TP impedance bridge includes:
connecting a high current terminal C_{H1} of first impedance Z₁ to a current output terminal of a first two-stage follower F_{Z1}, and connecting a high voltage terminal P_{H1} of the first impedance Z₁ to a voltage output terminal of the first two-stage follower F_{Z1}; connecting an input terminal of the first two-stage follower F_{Z1} to a ratio output tap of a ratio induction voltage divider through a switch connection, to thereby make a bridge ratio variable; and connecting a low voltage terminal P_{L1} of the first impedance Z₁ to a high terminal of a Kelvin balance;
connecting a high current terminal C_{H2} of second impedance Z₂ to a current output terminal of a second two-stage follower F_{Z2}, and connecting a high voltage terminal P_{H2} of the second impedance Z₂ to a voltage output terminal of the second two-stage follower F_{Z2}; and connecting a low voltage terminal P_{L2} of the second impedance Z₂ to a low terminal of the Kelvin balance; and
connecting an input terminal of the second two-stage follower F_{Z2} to the ratio induction voltage divider after connecting the input terminal of the second two-stage follower F_{Z2} in series with a differential signal injection transformer.

Compared to the related art, beneficial effects of the present disclosure are the follows.

The present disclosure can automatically satisfy the terminal-pair definition of the 4TP impedance; in the present disclosure, the follower is added to make the bridge ratio variable and isolate an effect of bridge load changes in the 4TP impedance bridge, thereby accelerating a balancing speed of the 4TP impedance bridge, and achieving accurate and fast comparative measurement having variable ratio and high precision of the 4TP AC impedance.

### BRIEF DESCRIPTION OF DRAWINGS

FIG. 1 illustrates a schematic diagram of a definition of 4TP impedance according to an embodiment of the present disclosure.

FIG. 2 illustrates a schematic diagram of using a follower to meet terminal-pair definition of impedance in the related art.

FIG. 3 illustrates a schematic diagram of a method for achieving terminal-pair definition of 4TP impedance according to an embodiment of the present disclosure.

FIG. 4 illustrates a schematic diagram of a 4TP impedance bridge in the related art.

FIG. 5 illustrates a schematic diagram of a 4TP impedance bridge according to an embodiment of the present disclosure.

### DETAILED DESCRIPTION OF EMBODIMENTS

The present disclosure will be described in detail in conjunction with drawings below.

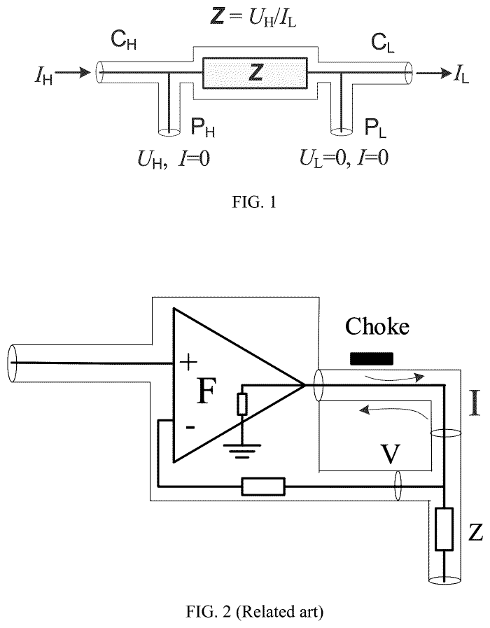

A principle of a terminal-pair definition of 4TP impedance is shown in FIG. 1, impedance satisfies definition conditions of 4TP impedance and the 4TP impedance is defined as Z=U_{H}/I_{L} when voltages and currents of four terminals of the impedance satisfy the following conditions: a current of a high voltage terminal U_{H} is 0, a voltage and a current of a low voltage terminal U_{L} are 0, a current of a high current terminal C_{H} is I_{H}, and a current of a low current terminal C_{L} is I_{L}.

In order to satisfy the definition conditions of the impedance, in a measurement circuit of the impedance, the definition conditions of the impedance are achieved by a method of configuring a power supply with adjustable amplitude and phase on a current terminal, and configuring a detector (NI) on a voltage terminal to measure flowed current. A high voltage terminal, a high current terminal, a low voltage terminal and a low current terminal of the measured impedance respectively satisfy the above definition conditions of 4TP impedance through adjusting an output of the power supply and combining the detector to determine. However, the measurement process needs to repeatedly adjust the output of the power supply, and to perform a null-pointing judgement, which leads to complicated steps and long period of the measurement of the 4TP impedance.

The astatic construction (metrological noun) is adopted to minimize an influence of mutual inductance coupling of an alternating current (AC) measurement circuit, therefore, an astatic characteristic of the measurement circuit needs to be ensured to achieve the definition of the 4TP AC impedance, that is, when a core wire current and an outer wire current (i.e., a current in a core wire of the coaxial wire and a current in an outer wire (i.e., shielding layer) of a coaxial line) of the coaxial line in the current terminal of the 4TP impedance are equal and reverse, magnetic fields generated by the core wire current and the outer wire current are offset outside the coaxial line, and no leakage magnetic field is presented. Meanwhile, terminal voltages are not affected by an external interference magnetic field. In the measurement circuit, the astatic construction needs to ensure that a core wire current and an outer wire current in each mesh (i.e., a minimum loop, which is a noun in circuit theory) of the circuit are equal and reverse.

A general method at present is to add a choke in a coaxial line mesh where an outer wire of the coaxial line is short circuited (i.e., the coaxial line is twined on a bracelet ring magnetic core) to ensure the above astatic requirements. In order to ensure the effect, the coaxial line needs to be twined on a magnetic core for 10-20 turns, which may lead to an increase of a length of a lead wire.

When the measured impedance Z satisfies the terminal-pair definition, an output terminal and a feedback terminal of a voltage follower can be used to be a current terminal and a voltage terminal of a terminal of the measured impedance, respectively. Specifically, as shown in FIG. 2, the output terminal of the voltage follower is connected to a high current terminal of the impedance through the coaxial line, an inverting input terminal of the voltage follower is connected to a high voltage terminal of the impedance through the coaxial line, and the output terminal and the inverting input terminal of the voltage follower are closed at a connection of the current terminal and the voltage terminal of the impedance to form a follower feedback loop. An astatic design (e.g., add the choke) of the circuit ensures that the core wire current and the outer wire current of the current terminal are equal and reverse. The feedback terminal of the follower does not have current and only provides a potential, and a definition requirement of the voltage terminal of the impedance is automatically satisfied.

A black thin solid line in FIG. 2 is the outer wire of the coaxial line connected with an outer shell of the voltage follower, and both are connected to a signal reference ground. A black thick solid line in FIG. 2 is a signal wire and the core wire of the coaxial line. Elliptical circles in FIG. 2 represent ports, that is, coaxial ports, which are coaxial terminals installed on a panel, and is connected to other ports through the coaxial line.

An ideal voltage follower can achieve a definition of a voltage terminal and a current terminal for four-wire resistors. However, from a perspective of the terminal-pair definition of the impedance, it is also necessary to consider a flow of the outer wire current. Therefore, a single voltage follower has the disadvantages of insufficient following accuracy and high output impedance.

The follower is used to achieve the measurement of the 4TP impedance, which requires the follower to have extremely high following accuracy and extremely low output impedance. The present disclosure adopts a two-stage follower with a buffer structure as a high accuracy follower. As shown in FIG. 3, the two-stage follower includes a first follower F₁, a second follower F₂ and a third follower F₃. The first follower F₁ is a first-stage follower, the second follower F₂ and the third follower F₃ are combined to be a second-stage follower. A power supply of the second follower F₂ and a power supply of the third follower F₃ are a same power supply ±V_{cc2}, and the second follower F₂ and the third follower F₃ are combined to form a follower with low output impedance, therefore, a combination of the second follower F₂ and the third follower F₃ forms the second-stage follower.

A power supply ±V_{cc} of the first-stage follower and the power supply ±V_{cc2} of the second-stage follower are independent of each other, and an output terminal of the first follower F₁ is connected to a center point of the power supply ±V_{cc2} of the second-stage follower.

Since the power supply ±V_{cc2} of the second-stage follower and the power supply ±V_{cc} of the first-stage follower are independent (i.e., isolated) of each other, a potential of the center point of the power supply ±V_{cc2} of the second-stage follower is changed with a floating of an input signal, that is, the potential of the center point of the power supply ±V_{cc2} of the second-stage follower is floatable relative to a ground potential. A following signal of the second-stage follower is obtained by subtracting an output signal of the first-stage follower from the input signal and adding into a final output signal of the second-stage follower, thus compensating a following error introduced by the first-stage follower through the second-stage follower, and a voltage following accuracy of the order of 10⁻⁷ can be achieved within an audio range, so as to achieve high accuracy voltage following.

An output terminal of the second follower F₂ is connected to a non-inverting input terminal of the third follower F₃, the third follower F₃ is achieved through a follower circuit, output impedance of the third follower F₃ is already low through a close-loop feedback, and when the third follower F₃ is combined with the second follower F₂ to form the second-stage follower, final output impedance is further decreased through a close-loop negative feedback, so that the output impedance is decreased by using the third follower F₃, which makes the output impedance of the follower circuit smaller than 1×10⁻⁵ ohms (Ω). The first follower F₁, the second follower F₂ and the third follower F₃ can be achieved by adopting an existing junction field-effect transistor (JFET) precision operational amplifier OPA627.

In an embodiment, an input terminal of the two-stage follower is V_{Input}, a current output terminal of the two-stage follower is Iₒᵤₜ, and a voltage output terminal of the two-stage follower is Vₒᵤₜ. The input terminal and the output terminal refer to the coaxial ports, and the coaxial ports include core wires and outer wires. The input terminal connected to another terminal refers to the core wires and the outer wires of the two terminals are respectively connected, and the output terminal is the same.

Specifically, the input terminal V_{Input} of the two-stage follower is connected to a non-inverting input terminal (corresponding to a + end in FIG. 3) of the first follower F₁ and a non-inverting input terminal (corresponding to a + end in FIG. 3) of the second follower F₂, individually, meanwhile, the input terminal V_{Input} is connected to an outer wire (i.e., reference ground) of the input terminal V_{Input} through an input resistance Rᵢₙ, that is, a core wire in a coaxial line of the input terminal V_{Input} is connected to the outer wire of the input terminal V_{Input} through the input resistance Rᵢₙ, and the outer wire is connected to ground, which is used to dispose a DC bias of an operational amplifier, the input resistance Rᵢₙ determines an input resistance of the two-stage follower, and the input resistance Rᵢₙ is generally selected as 10 megaohms (MΩ), 100 MΩ and 500 MΩ can be also selected according to actual needs.

An output terminal of the third follower F₃ is connected to the current output terminal Iₒᵤₜ, an inverting input terminal (corresponding to a − end in FIG. 3) of the second follower F₂ is connected to the voltage output terminal Vₒᵤₜ, an outer wire of the current output terminal Iₒᵤₜ is connected to a center point of the power supply ±V_{cc} of the first-stage follower, an outer wire of the voltage output terminal Vₒᵤₜ of the two-stage follower is connected to the outer wire of the input terminal V_{Input}, that is voltage reference ground.

A function of the follower is to achieve a current drive of the impedance and accurately follow the input voltage to the voltage terminal of the impedance, therefore, a power supply of the follower needs to provide a driving current. In order to avoid an irregular flow of an outer wire current of the current terminal and an outer wire current of the voltage terminal of the follower, the current terminal and the voltage terminal of the follower need to be disposed separately. A light black dotted line in FIG. 3 is current reference ground, that is, a shielding shell of the two-stage follower and the outer wire of the current output terminal (the shielding shell and the outer wire of the current output terminal are connected as a whole) are connected to the center point (i.e., the current reference ground) of the power supply ±V_{cc} of the two-stage follower, the black thin solid line is the outer wire of the coaxial line, that is the voltage reference ground, the elliptical circles in FIG. 3 represent the coaxial ports, which are connected to other ports through the coaxial line.

Moreover, when the two-stage follower is not externally connected to a measured impedance Z, the lead wire is not connected between the current output terminal Iₒᵤₜ and the voltage output terminal Vₒᵤₜ, in the present disclosure, the core wire and the outer wire of the current output terminal Iₒᵤₜ of the two-stage follower are connected to the core wire and the outer wire of the voltage output terminal Vₒᵤₜ of the two-stage follower through a first resistance R₁ and a second resistance R₂, respectively, that is, the core wire of the current output terminal Iₒᵤₜ is connected to the core wire of the voltage output terminal Vₒᵤₜ through the first resistance R₁, and the outer wire of the current output terminal Iₒᵤₜ is connected to the outer wire of the voltage output terminal Vₒᵤₜ through the second resistance R₂, so that a feedback loop, the voltage ground and the current ground of the follower are not in an open circuit state through the first resistance R₁ and the second resistance R₂, so as to ensure a normal operation of Iₒᵤₜ and Vₒᵤₜ of the two-stage follower during open circuit, and resistances of R₁ and R₂ are generally selected as 1 kilo-ohm (kΩ) and 50Ω.

When the two-stage follower is used to achieve the terminal-pair definition of the impedance, the current output terminal Iₒᵤₜ of the two-stage follower is connected to a high current terminal C_{H} of the impedance Z through the coaxial line, the voltage output terminal Vₒᵤₜ of the two-stage follower is connected to a high voltage terminal P_{H} of the impedance Z through the coaxial line. Since the core wires and the outer wires of the current output terminal Iₒᵤₜ and the voltage output terminal Vₒᵤₜ are individually shorted at a connection of C_{H} and P_{H} of the impedance Z (inside the 4TP impedance, core wires and outer wires of C_{H} and P_{H} are individually shorted), the first resistance R₁ and the second resistance R₂ are short circuited, and a voltage of the input terminal V_{Input} is followed to a definition point of the impedance Z. Definition points of the 4TP impedance are short connection points of the voltage terminal and the current terminal, and the definition points include high terminal definition points and low terminal definition points, in the present disclosure, only high terminal definition points are involved. When the close-loop feedback of the ideal follower is closed at the definition points of the impedance, the input voltage can be accurately followed to output points, that is the definition points of the impedance.

According to the terminal-pair definition of the impedance, the core wire current and the outer wire current of the current terminal of the impedance need to be equal and reverse, and the core wire current and the outer wire current of the voltage terminal need to be 0. Functions of the first resistance R₁ and the second resistance R₂ are to make the two-stage follower work normally when there is no external impedance. When the two-stage follower is externally connected with the impedance, and the first resistance R₁ and the second resistance R₂ are removed, the 4TP definition will be automatically satisfied. However, the first resistance R₁ and the second resistance R₂ are needed, thus settings for resistances of the first resistance R₁ and the second resistance R₂ need to satisfy certain requirements (e.g., set as 1 kΩ and 50Ω), vast majority of current still flows between the core wire and the outer wire at the current terminal, and effects of the core wire current and the outer wire current of the voltage terminal can be ignored, which makes the core wire current and the outer wire current of the current output terminal Iₒᵤₜ of the two-stage follower equal and reverse, and makes almost no current to flow through the core wire and the outer wire of the voltage output terminal Vₒᵤₜ, so as to achieve the astatic design of the measurement circuit, and solve a problem of must using the choke to achieve the astatic design.

In the present disclosure, the current reference ground and the voltage reference ground of the follower are separated (the light black dotted line in FIG. 3 represents the current reference ground, and the black thin solid line in FIG. 3 represents the voltage reference ground), the current reference ground is connected to the voltage reference ground through the second resistance R₂, and the astatic design of the circuit ensures that the core wire current and the outer wire current in the current terminal are equal and reverse. The feedback terminal of the follower has no current and only provides a potential, and satisfying the definition of the voltage terminal of the impedance.

In an embodiment, the present disclosure further provides an application method for achieving a fast comparative measurement of the 4TP impedance bridge by using the above method, that is, two sets of two-stage induction voltage divider terminal-pair definition structure are used to replace two source combination networks in the traditional 4TP impedance bridge, so as to achieve the terminal-pair definition of the compared 4TP impedance.

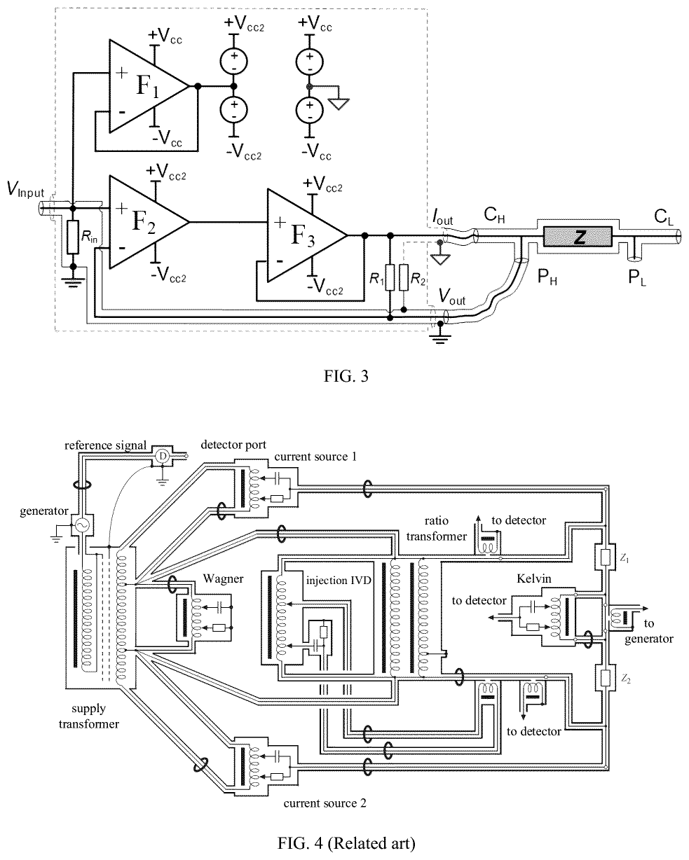

Specifically, a principle of a classic 4TP AC coaxial bridge based on an induction ratio arm (i.e., induction voltage divider) is shown in FIG. 4, in a measurement bridge of the 4TP AC impedance, the definition condition of each terminal-pair of the 4TP impedance needs to be satisfied, thus a load balance needs to be performed on each current terminal-pair and each voltage terminal-pair. As shown in FIG. 4, a whole bridge includes: three induction voltage dividers such as a ratio induction voltage divider, a source induction voltage divider and an injection induction voltage divider, multiple auxiliary balances and source combination networks, multiple chokes, multiple detectors and the like key components. Specifically, a signal generator sends a signal to drive the source induction voltage divider to supply power to the bridge, and a synchronous reference signal of the signal generator is connected to the detector, high and low power supply terminals of the source induction voltage divider are individually connected to high and low power supply terminals of the ratio induction voltage divider and high and low power supply terminals of a Wagner balance, an output of a source combination network 1 is connected to a high current terminal of a first impedance Z₁, an output of a source combination network 2 is connected to a high current terminal of a second impedance Z₂, a low current terminal C_{L1} of the first impedance Z₁ is connected in series with a signal injection transformer and then connected to a low current terminal C_{L1} of the second impedance Z₂, a high potential terminal of the first impedance Z₁ is connected in series with a detector transformer and then connected to a high terminal of the ratio induction voltage divider, a low potential terminal of the first impedance Z₁ is connected to a high terminal of a Kelvin balance, a high potential terminal of the second impedance Z₂ is connected in series with a detector transformer and a differential signal injection transformer and then connected to a low terminal of the ratio induction voltage divider, and a low potential terminal of the second impedance Z₂ is connected to a low terminal of the Kelvin balance. Auxiliary balancing measures of the bridge include: two terminal-pair definition balance of high terminals of the compared impedance, the Wagner balance and the Kelvin balance. The above four auxiliary balances and a main balance condition of the bridge need to be satisfied by the bridge at the same time, so that one measurement can be completed.

A complexity of the 4TP bridge is made to be more than that of the two-terminal-pair bridge by multiple terminal-pair definition balances and the auxiliary balances. To measure the existing 4TP bridge once, it is necessary to carry out load balance and main balance repeatedly until all the 4TP definition conditions are satisfied, and the operation process is time-consuming and cumbersome.

In the present disclosure, the fast comparative measurement of the 4TP impedance can be achieved by using the above fast achievement method of using a two-stage follower to satisfy the terminal-pair definition of the impedance.

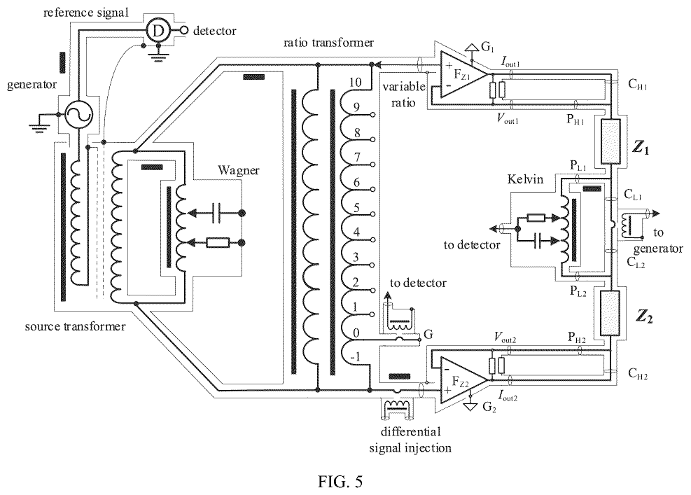

As shown in FIG. 5, two sets of two-stage followers F_{Z1} and F_{Z2} are used to achieve a terminal-pair definition of high voltage terminals and high current terminals of compared impedance Z₁ and Z₂ in a 4TP impedance bridge, and the two sets of two-stage followers F_{Z1} and F_{Z2} replace the two sets of the source combination networks in the traditional 4TP bridge, which greatly reduces the complexity of the 4TP bridge. Meanwhile, a bridge device and an external load are isolated by adopting the followers, thus greatly reducing auxiliary balance correlation and balance times of the bridge.

Specifically, a high current terminal C_{H1} of the first impedance Z₁ is connected to a current output terminal of the first two-stage follower F_{Z1}, a high voltage terminal P_{H1} of the first impedance Z₁ is connected to a voltage output terminal of the first two-stage follower F_{Z1}, and an input terminal of the first two-stage follower F_{Z1} is connected to a ratio output tap 10 of a ratio induction voltage divider, an addition of the follower isolates a bridge load, and the input terminal of the first two-stage follower F_{Z1} is connected to any ratio output taps (e.g., taps 1-10 in FIG. 5) of the ratio induction voltage divider through a switching connection to form a variable bridge ratio, which greatly increases a measurement range of the 4TP bridge. A low voltage terminal P_{L1} of the first impedance Z₁ is connected to a high terminal of a Kelvin balance, a high current terminal C_{H2} of the second impedance Z₂ is connected to a current output terminal of the second two-stage follower F_{Z2}, a high voltage terminal P_{H2} of the second impedance Z₂ is connected to a voltage output terminal of the second two-stage follower F_{Z2}, and an input terminal of the second two-stage follower F_{Z2} is connected in series with a differential signal injection transformer and then connected to a ratio output tap −1 of the ratio induction voltage divider; and a low current terminal C_{L1} of the first impedance Z₁ is connected to a low current terminal C_{L2} of the second impedance Z₂ through a signal injection transformer, a low voltage terminal P_{L1} of the first impedance Z₁ is connected to the high terminal of the Kelvin balance (a choke needs to be added to a formed mesh), a low voltage terminal P_{L2} of the second impedance Z₂ is connected to a low terminal of the Kelvin balance, when conditions of the Kelvin balance are satisfied, voltages and currents of the low voltage terminal Pu of the first impedance Z₁ and the low voltage terminal P_{L2} of the second impedance Z₂ are approximately 0, and core wire currents and outer wire currents of the low current terminals C_{L1} and C_{L2} are equal and reverse, so as to satisfy 4TP definitions of the first impedance Z₁ and the second impedance Z₂. Connection ways of other parts are the same as the existing bridge, that is, a high power supply terminal and a low power supply terminal of the ratio induction voltage divider are individually connected to a high power supply terminal and a low power supply terminal of a Wagner balance, a signal generator sends a signal to drive a source induction voltage divider to supply power to the bridge, a synchronous reference signal of the signal generator is connected to a detector, a high power supply terminal and a low power supply terminal of the source induction voltage divider are individually connected to the high power supply terminal and the low power supply terminal of the ratio induction voltage divider and the high power supply terminal and the low power supply terminal of the Wagner balance.

Verify based on actual operation, the Wagner balance of the power and the Kelvin balance of the detector in the bridge of the present disclosure only need to be balanced once, and there is basically no need to make adjustments. A single measurement of the 4TP bridge can be completed by completing a main balance of the bridge after completing an initial setting of a bridge auxiliary balance, which greatly improves the measurement speed. Under 1 kilohertz (kHz), an uncertainty level of the impedance measurement of the 4TP impedance bridge can reaches 1×10⁻⁷ (k=2).

It is different from a conventional method for achieving the definition of the 4TP impedance by using the source combination network and the detector, the present disclosure proposes a fast achievement method of comparative measurement of the 4TP impedance, and the method can automatically satisfy the 4TP definition of the impedance, the follower is added to isolate an effect of bridge load changes, thereby accelerating a balancing speed of the 4TP impedance bridge, and achieving accurate and fast comparative measurement having high precision of the 4TP AC impedance, and a measurement accuracy of the impedance is merely limited by a following accuracy of a precision follower; and the present disclosure is also applicable to a precision measurement instrument or similar measurement systems for AC parameters.

The terminal-pair definition of the AC impedance is satisfied by adopting the two-stage followers in the present disclosure, the fast comparative measurement of the 4TP impedance is achieved, the present disclosure can be applied in the field of fast automatic measurement of the 4TP impedance, which has a great significance for commercializing a terminal-pair measurement technology and improving performances of metrological instruments.

The above technical solution is merely an embodiment of the present disclosure, for those skilled in the art, it is easy to make various types of improvements or deformations based on principles disclosed in the present disclosure, which are not limited to the technical solution described in the specific embodiments of the present disclosure. Therefore, the previous description is only exemplary and does not have restrictive significance.

What is claimed is:

1. A method for achieving terminal-pair definition of four-terminal-pair (4TP) impedance, comprising:
connecting a current output terminal of a two-stage follower to a high current terminal of impedance through a coaxial line, and connecting a voltage output terminal of the two-stage follower to a high voltage terminal of the impedance through the coaxial line, to thereby make a current of the high voltage terminal of the impedance be zero, and a core wire current and an outer wire current of the high current terminal equal and reverse;
wherein the two-stage follower comprises: a first follower F₁, a second follower F₂ and a third follower F₃; and the first follower F₁ is a first-stage follower, the second follower F₂ and the third follower F₃ are combined to be a second-stage follower;
wherein a power supply ±V_{cc} of the first-stage follower and a power supply ±V_{cc2} of the second-stage follower are independent of each other, and an output terminal of the first follower F₁ is connected to a center point of the power supply ±V_{cc2} of the second-stage follower;
wherein the method further comprises:
connecting an output terminal of the second follower F₂ to a non-inverting input terminal of the third follower F₃;
connecting a core wire of the current output terminal Iₒᵤₜ of the two-stage follower to a core wire of the voltage output terminal Vₒᵤₜ of the two-stage follower through a first resistance R₁, and connecting an outer wire of the current output terminal Iₒᵤₜ to an outer wire of the voltage output terminal Vₒᵤₜ through a second resistance R₂;
connecting an input terminal V_{Input} of the two-stage follower to a non-inverting input terminal of the first follower F₁ and a non-inverting input terminal of the second follower F₂, individually, and connecting the input terminal V_{Input} of the two-stage follower to an outer wire of the input terminal V_{Input} through an input resistance Rᵢₙ, that is, connecting the input terminal V_{Input} of the two-stage follower to reference ground through the input resistance Rᵢₙ;
connecting an output terminal of the third follower F₃ to the current output terminal Iₒᵤₜ of the two-stage follower, and connecting an inverting input terminal of the second follower F₂ to the voltage output terminal Vₒᵤₜ of the two-stage follower;
connecting the outer wire of the current output terminal Iₒᵤₜ of the two-stage follower to a center point of the power supply ±V_{cc} of the first-stage follower; and
connecting the outer wire of the voltage output terminal Vₒᵤₜ of the two-stage follower to the outer wire of the input terminal V_{Input}.

2. A method for achieving comparative measurement of a 4TP impedance bridge, comprising: applying the method for achieving terminal-pair definition of 4TP impedance as claimed in claim 1 to achieve the comparative measurement of the 4TP impedance bridge.

3. The method for achieving the comparative measurement of the 4TP impedance bridge as claimed in claim 2, wherein the method comprises:
connecting a high current terminal C_{H1} of first impedance Z₁ to a current output terminal of a first two-stage follower F_{Z1}, and connecting a high voltage terminal P_{H1} of the first impedance Z₁ to a voltage output terminal of the first two-stage follower F_{Z1}; connecting an input terminal of the first two-stage follower F_{Z1} to a ratio output tap of a ratio induction voltage divider through a switch connection, to thereby make a bridge ratio variable; and connecting a low voltage terminal P_{L1} of the first impedance Z₁ to a high terminal of a Kelvin balance;
connecting a high current terminal C_{H2} of second impedance Z₂ to a current output terminal of a second two-stage follower F_{Z2}, and connecting a high voltage terminal P_{H2} of the second impedance Z₂ to a voltage output terminal of the second two-stage follower F_{Z2}; and connecting a low voltage terminal P_{L2} of the second impedance Z₂ to a low terminal of the Kelvin balance; and
connecting an input terminal of the second two-stage follower F_{Z2} to the ratio induction voltage divider after connecting the input terminal of the second two-stage follower F_{Z2} in series with a differential signal injection transformer.
